(19) United States
(12) Patent Application Publication
(10) Pub. No.: US 2025/0329559 A1
(43) Pub. Date: Oct. 23, 2025

(54) LOAD LOCK WITH DIAGNOSTIC AND REMEDIATION CAPABILITIES

(71) Applicant: Applied Materials, Inc., Santa Clara, CA (US)

(72) Inventors: Chang Ke, Sunnyvale, CA (US); Changgong Wang, San Jose, CA (US); Glen Mori, Gilroy, CA (US); Ming-Hui Chiu, Campbell, CA (US)

(21) Appl. No.: 18/824,784

(22) Filed: Sep. 4, 2024

Related U.S. Application Data
(60) Provisional application No. 63/636,068, filed on Apr. 18, 2024.

(51) Int. Cl. H01L 21/67; G05D 16/20

(52) U.S. Cl. CPC H01L 21/67201; G05D 16/208

(57) ABSTRACT

A load lock including sensing and recovery subsystems to remediate a measured condition within the load lock. The sensing subsystem can use a variety of sensors to measure the conditions within a processing chamber, and a computing subsystem can selectively activate a the recovery subsystem or remediation subsystem of the recovery subsystem to remediate an aspect of the measured conditions, such as chamber contamination, as deemed necessary based on the measured conditions. The remediation subsystem can include several mechanisms, including a gas purge of the chamber. The overall system can work to regulate chamber contamination, wafer contamination, or chamber component integrity.

### RELATED APPLICATIONS

This patent application claims the benefit under 35 U.S.C. § 119(e) of U.S. Provisional Application No. 63/636,068, filed Apr. 18, 2024, which is incorporated by reference herein.

### TECHNICAL FIELD

Embodiments of the present disclosure relate generally to a load lock for transitioning a substrate or a wafer to further processing devices and chambers, and in particular to a load lock system capable of performing self-diagnostics and remediation.

### BACKGROUND

An electronic device manufacturing system may include a factory interface (which may be, e.g., an Equipment Front End Module or EFEM) configured to receive substrates upon which electronic devices may be manufactured, a transfer chamber for transferring substrates to and from process chambers, and one or more load locks separating the transfer chamber from the factory interface.

Internal conditions of a load lock can degrade over time. For example, the load lock may become dirty and/or contaminated, components within and of the load lock may mechanically degrade or fail, and so on. To address gradual contamination and particle buildup within load locks, engineers traditionally schedule regular maintenance and cleaning of load locks. For example, a load lock may be scheduled for cleaning every three months without actual knowledge about current conditions within the load lock.

In some instances, engineers will take a load lock out of service to run a particle test on a test substrate in the load lock. The test substrate may then be removed from the load lock and measured to determine a quantity of particles on the test substrate using an external metrology device. Such periodic testing can be used to determine when to perform cleaning of the load lock. However, because taking the load lock out of service and running the particle test is costly in terms of tool down-time and engineer time, such tests are performed infrequently (e.g., once a day). As a result, often multiple product substrates are processed in a dirty or contaminated load lock before the load lock is determined to be dirty or contaminated. Additionally, most particle tests that are performed show an uncontaminated load lock, unnecessarily reducing tool up-time.

Unsatisfactory processing conditions that go unnoticed and are left unattended can jeopardize the substrate, substrate-including end products and equipment, decrease throughput, and increase costs through system down time and part maintenance.

### SUMMARY

In an aspect of the disclosure, a load lock of an electronic device manufacturing system is provided. The load lock comprises a substrate support configured to hold a substrate, at least one sensor to generate a measurement reflective of a condition within the load lock, a computing subsystem configured to: process the measurement to determine the condition within the load lock and determine whether to perform a remedial action based on the condition of the load lock; and a recovery subsystem, configured to perform the remedial action responsive to a determination to perform the remedial action.

In an aspect of the disclosure, a load lock of an electronic device manufacturing system is provided. The load lock comprises an inlet gas line comprising a first valve, an outlet gas line, a vacuum pump coupled to the outlet gas line, and a controller operatively coupled to the first valve and the vacuum pump, wherein the controller is to perform an automated clean cycle of the load lock, and wherein to perform the automated clean cycle the controller is to: set a target pressure of between 10 mT and 1 Torr for the vacuum pump and actuate the first valve to cause an initial pressure ramp of greater than 10 Torr/sec.

In an aspect of the disclosure, a load lock of an electronic device manufacturing system and a method for performing remedial actions within the load lock is provided. The method for performing remedial actions in a load lock comprises generating a measurement of a condition within a load lock via at least one sensor, processing the measurement via a computing subsystem to determine the condition within the load lock, determining, via the computing subsystem, whether to perform a remedial action based on the condition of the load lock, and performing the remedial action, via a recovery subsystem, responsive to a determination to perform the remedial action.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

The drawings, described below, are for illustrative purposes only and are not necessarily drawn to scale. The drawings are not intended to limit the scope of the disclosure in any way.

FIG. 1A illustrates a top-down view of an exemplary embodiment of a substrate manufacturing system, including a load lock system, and its placement among other processing chambers and equipment in a factory setting.

FIG. 1B illustrates a cut-away side view of an exemplary embodiment of a load lock system with an associated sensing and recovery subsystem.

FIG. 2 illustrates an exemplary embodiment of a production flow associated with the use of a load lock system.

FIG. 3 illustrates an exemplary embodiment of a computing subsystem associated with the use of a load lock system.

FIG. 4 illustrates an exemplary embodiment of the hardware and control algorithm associated with the use of a load lock system.

FIG. 5A illustrates an embodiment of a characterization chart of a standard gas purge process.

FIG. 5B illustrates an embodiment of a characterization chart of a purge clean process.

FIG. 6 illustrates an embodiment of a diagrammatic representation of a computing device associated with a substrate manufacturing system.

### DETAILED DESCRIPTION OF EMBODIMENTS

Embodiments described herein are related to a load lock system and load lock capable of self-diagnostics and automated recovery. The load lock system and load lock may be used in a processing or manufacturing system, such as a substrate processing or manufacturing system.

Embodiments described herein are directed to a load lock system that includes one or more sensors usable to perform self-diagnosis and/or one or more automated recovery and/or prevention systems capable of performing automated remedial actions (e.g., such as purge clean cycles). In embodiments the load lock system may further include one or more contamination and/or degradation prevention systems. The load lock system may generate measurements of substrates, components of the load lock, an internal environment of the load lock, and so on, on a periodic or continuous basis. For example, measurements may be made for each substrate passing through the load lock, such as before a substrate enters the load lock, while the substrate is in the load lock and/or after the substrate leaves the load lock. The load lock system may process the measurement(s) to determine one or more conditions of the substrate, of one or more component(s) of the load lock, of an environment of the load lock, and so on. The determined condition associated with the measurement may include a quantity of foreign particles and/or a quantity of vapor contaminants (e.g., such as moisture and/or organics) in some embodiments. The determined condition or conditions may be compared to one or more criteria. If the determined condition or conditions satisfies the one or more criteria associated with a remedial action, then the remedial action may be automatically recommended, scheduled and/or initiated. Accordingly, problematic conditions within the load lock can be detected and/or predicted automatically without taking the load lock out of service, and without running test processes on test substrates in the load lock. As a result, up-time of the load lock may be significantly higher than that of traditional load locks. Additionally, any problematic conditions of the load lock may be predicted or may be detected immediately after a single substrate might have been exposed to the problematic conditions (e.g., high particle contamination, high humidity, organic contamination, and so on) and before any additional substrates are exposed to the problematic conditions.

In embodiments, the load lock system includes an automated recovery and/or prevention system that can be activated responsive to the load lock system detecting a problematic condition (e.g., responsive to determining that the load lock has a particle count that is higher than a particle count threshold) or predicting a future problematic condition. In one embodiment, the automated recovery system includes a valve connected to a load lock gas inlet, a vacuum pump connected to a load lock gas outlet, and controller configured to performed an automated purge clean process on the load lock. To perform an automated purge clean process, the controller may open the valve at the gas inlet of the load lock to permit gas to flow into the load lock at a high velocity while the load lock is under vacuum conditions. The high velocity inflow of gas may disturb particles accumulated on various surfaces of an interior of the load lock and cause those particles to become airborne. The purge clean process may further include setting a vacuum pump coupled to an outlet of the load lock to a low vacuum pressure that is below a standard operating vacuum pressure of the load lock. The valve at the inlet may be closed after a time to permit the load lock to reach vacuum pressures again, followed by an additional purge clean cycle in which the valve is again opened to permit a high velocity stream of gas to again enter the load lock. Multiple purge clean cycles may be performed according to a purge clean recipe in embodiments. By automatically initiating a purge clean process responsive to detecting that the load lock is dirty, the load lock system is able to clean the load lock on an as-needed basis rather than relying on periodic scheduled maintenance that is disconnected from an actual current state of the load lock. Additionally, the load lock system is able to clean the load lock without involving technicians and without having the load lock opened up and exposed to an external environment (which generally causes the load lock to go through a lengthy requalification process). Accordingly, the load lock system described in embodiments provides many advantages over conventional load locks.

In embodiments, a load lock is an autonomous load lock or semi-autonomous load lock that can make decisions locally without data transfer to remote computing devices. In embodiments, a smart load lock (also referred to as an autonomous load lock or semi-autonomous load lock) is capable of determining when to perform maintenance such as a purge clean process, and is further capable of performing such maintenance in an automated fashion without involvement of a technician. In embodiments, a smart load lock processes sensor data using a trained machine learning model, where the trained machine learning model generates an output such as a prediction of a future problem and/or a recommendation to perform maintenance and/or some other remedial action.

In some embodiments, trained machine learning models are edge-based models that execute on the load lock and/or substrate processing systems (e.g., platforms, transfer chambers, mainframes, factory interfaces, and/or tool clusters) that include the load lock. Alternatively, trained machine learning models are executed on a fabrication facility (“fab”) level computing device or a remote server computing device. In some embodiments, training of the machine learning models may be performed remotely, after which trained machine learning models may be transferred to load lock controllers and/or substrate processing systems.

In an example, a decision of whether to schedule cleaning (e.g., automated cleaning) of a load lock chamber may be made after a substrate is cycled through the load lock chamber and before a subsequent substrate is cycled through the load lock chamber. For example, a decision to perform a purge clean process on a smart load lock may be made within 1-5 minutes of a substrate being cycled through the load lock, within less than a minute of the substrate being cycled through the load lock, or even within a few seconds or fractions of a second of the substrate being cycled through the load lock. Such quick response time reduces an exposure of product substrates (substrates that will result in products of devices that will be sold to customers) to load locks that are out of specification and that could cause contamination of the substrates and/or failure of product that is ultimately manufactured.

The components of the embodiments as generally described and illustrated in the figures herein can be arranged and designed in a wide variety of different configurations. Thus, the detailed description of various embodiments, as represented in the figures, is not intended to limit the scope of the present disclosure but is merely representative of various embodiments. While various aspects of the embodiments are presented in drawings, the drawings are not necessarily drawn to scale unless specifically indicated. The phrase “coupled to” is broad enough to refer to any suitable coupling or other form of interaction between two or more entities, including direct and/or indirect mechanical, fluidic and thermal interaction. Thus, two components may be coupled to each other even though they are not in direct contact with each other. The phrases “attached to” or “attached directly to” refer to interaction between two or more entities which are in direct contact with each other and/or are separated from each other only by a fastener of any suitable variety (e.g., mounting hardware or an adhesive). The phrase “fluid communication” is used in its ordinary sense, and is broad enough to refer to arrangements in which a fluid (e.g., a gas or a liquid) can flow from one element to another element when the elements are in fluid communication with each other.

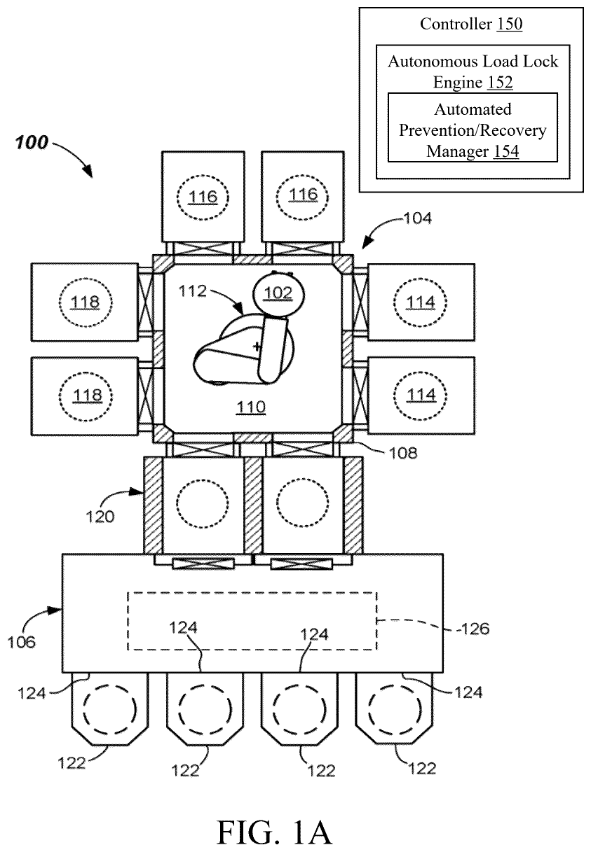

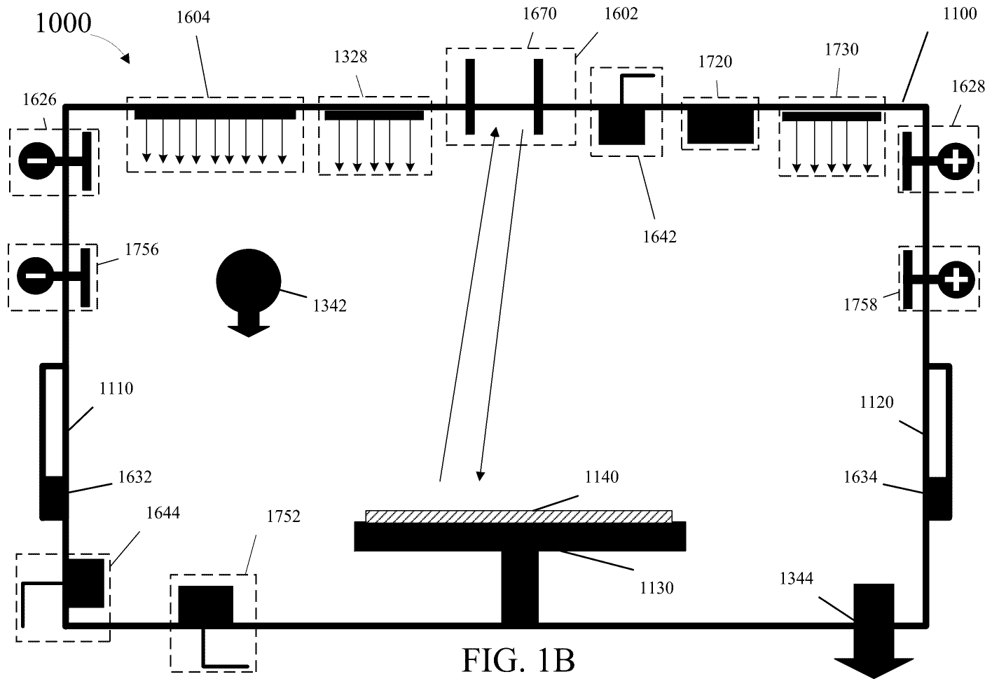

Referring now to the figures, FIG. 1A is a diagram of a cluster tool 100 (also referred to as a system, substrate processing system or manufacturing system) that is configured for substrate fabrication in accordance with at least some embodiments of the disclosure. In an exemplary embodiment, a manufacturing system (e.g., cluster tool 100) may comprise a processing portion 104, a transfer chamber 110, a load lock 120, a factory interface 106, and substrate carriers 122 or front opening unified pods (FOUPs). Processing portion 104 may comprise a plurality of process chambers 114, 116, and 118, wherein specific and controlled substrate manufacturing processes occur. Transfer chamber 110 may house a transfer robot (robot arm 112) comprising a substrate transfer mechanism, or end effector (substrate transfer mechanism and end effector will be used interchangeable moving forward in the disclosure) that may transport substrates 102. Transfer chamber 110 may be in transfer chamber housing 108. Load lock 120 may interface with both the processing portion 104 and the factory interface 106. Factory interface 106 may comprise a factory interface robot 126, for transferring substrates to and from the carriers 122 and the load lock 120. Factory interface may further comprise a plurality of load ports 124 for receiving carriers 122 carrying one or more substrates. Transfer chamber 110 is generally maintained at vacuum pressure levels, while factory interface 106 is generally maintained at atmospheric pressure.

In some embodiments, transfer chamber 110, process chambers 114, 116, and 118, and load lock 120 may be maintained at a vacuum level. The vacuum level for the transfer chamber 110 may range from about, e.g., 1 mTorr (or about 5 mT, 10 mT, 15 mT, 20 mT, 50 mT, 100 mT, etc.) to about 80 Torr (or about 0.5 Torr, 0.8 Torr, 1 Torr, 5 Torr, 20 Torr, 50 Torr, etc.). Other vacuum levels may be used.

The factory interface robot 126 is configured to transfer the substrate from the carriers (FOUPs) 122 to load locks 120 through load lock doors. The number of load locks can be more or less than two but for illustration purposes only, two load locks 120 are shown with each load lock having a door (e.g., a slit valve) to connect it to the factory interface 106 and a door to connect it to the transfer chamber 110. Load locks 120 may or may not be batch load locks (e.g., load locks that can hold a plurality of substrates at a time). In embodiments, the load locks are smart load locks capable of performing self-diagnosis and/or automated prevention and/or recovery.

The load locks 120, under the control of a controller 150, can be maintained at either an atmospheric pressure environment or a vacuum pressure environment, and serve as an intermediary or temporary holding space for a substrate that is being transferred to/from the transfer chamber 110. The transfer chamber includes robot arm 112 that is configured to transfer the substrate from the load locks 120 to one or more of the plurality of processing chambers 114, 116, 118 (also referred to as process chambers), or to one or more pass-through chambers (also referred to as vias), without vacuum break, i.e., while maintaining a vacuum pressure environment within the transfer chamber 110 and the plurality of processing chambers 114, 116, 118.

A door, e.g., a slit valve door, connects each respective load lock 120 to the transfer chamber 110. The plurality of processing chambers 114, 116, 118 are configured to perform one or more processes. Examples of processes that may be performed by one or more of the processing chambers 114, 116, 118 include cleaning processes (e.g., a pre-clean process that removes a surface oxide from a substrate), anneal processes, deposition processes (e.g., for deposition of a cap layer, a hard mask layer, a barrier layer, a bit line metal layer, a barrier metal layer, etc.), etch processes, and so on. Examples of deposition processes that may be performed by one or more of the process chambers include physical vapor deposition (PVD), chemical vapor deposition (CVD), atomic layer deposition (ALD), and so on. Examples of etch processes that may be performed by one or more of the process chambers include plasma etch processes.

Controller 150 (e.g., a tool and equipment controller, a tool cluster controller, etc.) may control various aspects of the cluster tool 100, e.g., gas pressure in the processing chambers, individual gas flows, spatial flow ratios, plasma power in various process chambers, temperature of various chamber components, radio frequency (RF) or electrical state of the processing chambers, and so on. The controller 150 may receive signals from and send commands to any of the components of the cluster tool 100, such as the robot arms 112, 126, process chambers 114, 116, 118, load locks 120, slit valve doors, and/or one or more sensors, and/or other processing components of the cluster tool 100. The controller 150 may thus control the initiation and cessation of processing, may adjust a deposition rate and/or target layer thickness, may adjust process temperatures, may adjust a type or mix of deposition composition, may adjust an etch rate, may initiate automated prevention and/or recovery processes on the load lock 120, and the like. The controller 150 may further receive and sensor measurement data (e.g., optical measurement data, vibration data, spectrographic data, particle detection data, temperature data, etc.) from various sensors and make decisions based on such measurement data.

In various embodiments, the controller 150 may be and/or include a computing device such as a personal computer, a server computer, a programmable logic controller (PLC), a microcontroller, and so on. The controller 150 may include (or be) one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. The controller 150 may include a data storage device (e.g., one or more disk drives and/or solid state drives), a main memory, a static memory, a network interface, and/or other components. The processing device of the controller 150 may execute instructions to perform any one or more of the methodologies and/or embodiments described herein. The instructions may be stored on a computer readable storage medium, which may include the main memory, static memory, secondary storage and/or processing device (during execution of the instructions). In some embodiments, controller 150 is a dedicated controller for load lock(s) 120.

In embodiments, the processing device and memory of controller 150 have an increased capacity as compared to processing power and memory size of traditional controllers for cluster tools. In embodiments, the processing device and memory are sufficient to handle parallel execution and use of multiple trained machine learning models, as well as training of the machine learning models. For example, the memory and processing device may be sufficient to handle parallel execution of 2-15 (e.g., 3, 4, 5, 6, 7, 8, 9, 10, etc.) different machine learning models (e.g., one or more for each of the process chambers 114, 116, 118, and/or load locks 120).

In one embodiment, the controller 150 includes an autonomous load lock engine 152. The autonomous load lock engine 152 may be implemented in hardware, firmware, software, or a combination thereof. The autonomous load lock engine 152 may be configured to receive and process measurement data generated by one or more sensors of load locks 120 during and/or after cycling of substrates through the load locks. The sensor measurements may include temperature measurements, pressure measurements, particle measurements, spectrographic measurements, vibration measurements, accelerometer measurements, voltage measurements, current measurements, resistance measurements, time measurements, optical measurements (e.g., such as optical emission spectrometry measurements and/or reflectometry measurements), position measurements, humidity measurement, part health measurements, and/or other types of measurements. Some example measurements include a chamber pressure (e.g., which may be measured in mTorr), OES spectra measurements for one or more wavelengths or frequencies (e.g., for wavelengths of 3870 nm, 7035 nm, 775 nm, and so on), one or more substrate support/heater temperatures, one or more substrate temperatures, and so on. Some or all of these measurements may be combined to generate a feature vector that is input into a trained machine learning model of the autonomous tool engine 121.

The autonomous load lock engine 152 running on controller 150 may include one or more rules-based engines and/or trained machine learning models for controlling and/or making decisions for one or more load locks. The one or more trained machine learning models may have been trained to receive sensor measurements from and/or associated with a load lock 120 and to make a prediction, classification or determination about the load lock. Each of the trained machine learning models may be associated with a different decision-making process for a load lock in embodiments. Alternatively, one or a few trained machine learning models may be associated with multiple decision-making processes for a load lock in embodiments.

In one embodiment, one or more of the trained machine learning models is a regression model trained using regression. Examples of regression models are regression models trained using linear regression or Gaussian regression. A regression model predicts a value of Y given known values of X variables. The regression model may be trained using regression analysis, which may include interpolation and/or extrapolation. In one embodiment, parameters of the regression model are estimated using least squares. Alternatively, Bayesian linear regression, percentage regression, leas absolute deviations, nonparametric regression, scenario optimization and/or distance metric learning may be performed to train the regression model.

In one embodiment, one or more of the trained machine learning models are decision trees, random forests, support vector machines, or other types of machine learning models.

In one embodiment, one or more of the trained machine learning models is an artificial neural network (also referred to simply as a neural network). The artificial neural network may be, for example, a convolutional neural network (CNN) or a deep neural network. In one embodiment, processing logic performs supervised machine learning to train the neural network.

Artificial neural networks generally include a feature representation component with a classifier or regression layers that map features to a target output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs). The neural network may be a deep network with multiple hidden layers or a shallow network with zero or a few (e.g., 1-2) hidden layers. Deep learning is a class of machine learning algorithms that use a cascade of multiple layers of nonlinear processing units for feature extraction and transformation. Each successive layer uses the output from the previous layer as input. Neural networks may learn in a supervised (e.g., classification) and/or unsupervised (e.g., pattern analysis) manner. Some neural networks (e.g., such as deep neural networks) include a hierarchy of layers, where the different layers learn different levels of representations that correspond to different levels of abstraction. In deep learning, each level learns to transform its input data into a slightly more abstract and composite representation.

One of more of the trained machine learning models may be recurrent neural networks (RNNs). An RNN is a type of neural network that includes a memory to enable the neural network to capture temporal dependencies. An RNN is able to learn input-output mappings that depend on both a current input and past inputs. The RNN will address past and future measurements and make predictions based on this continuous measurement information. For example, sensor measurements may continually be taken during a process, and those sets of measurements may be input into the RNN sequentially. Current sensor measurements and prior sensor measurements may affect a current output of the trained machine learning model. One type of RNN that may be used is a long short term memory (LSTM) neural network.

Some trained machine learning models of an autonomous load lock engine 152 use all sensor measurements generated by a load lock. Some trained machine learning models of an autonomous load lock engine 152 use a subset of generated sensor measurements.

In one embodiment, autonomous load lock engine 152 includes an automated prevention and/or recovery manager 154. Automated prevention and/or recovery manager 154 may include one or more rules-based systems and/or one or more trained machine learning models that are trained to receive sensor measurements of a load lock and to output a decision as to whether or not a prevention or recovery action such as maintenance should be performed on the load lock.

Controller 150 may be operatively connected to a server (not shown). The server may be or include a computing device that operates as a factory floor server that interfaces with some or all tools in a fabrication facility. The server may perform training to generate the trained machine learning models, and may send the trained machine learning models to autonomous load lock engine 152 on controller 150. Alternatively, the machine learning models may be trained on controller 150.

Training of a neural network may be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset. In high-dimensional settings, such as large images, this generalization is achieved when a sufficiently large and diverse training dataset is made available.

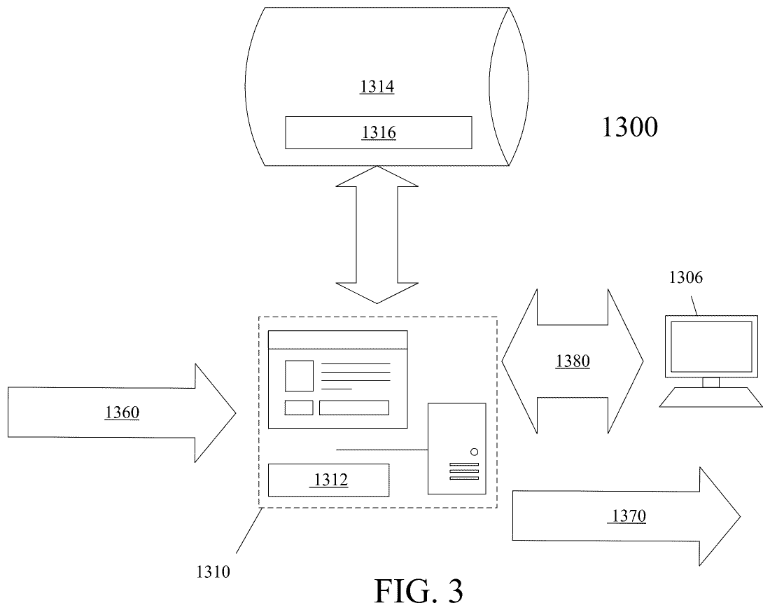

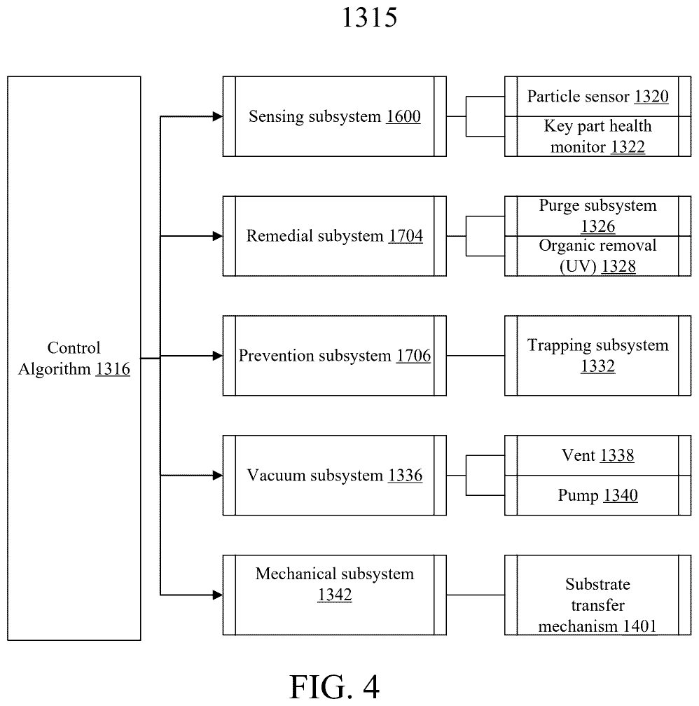

In a further exemplary embodiment, FIG. 1B illustrates a load lock system 1000 associated with a load lock 1100 or load lock chamber 1100 (load lock and load lock chamber will be used interchangeably moving forward in this disclosure) that may be associated with a substrate processing system. Load lock system 1000 may comprise a computing subsystem (which may correspond to computing subsystem 1300 of FIGS. 3 and 4), a sensing subsystem (which may correspond to sensing subsystem 1600 of FIG. 4), a recovery subsystem (which may correspond to recovery subsystem 1700 of FIG. 4), and/or a load lock 1100. The load lock 1100 may further comprise a first door portion 1110, a second door portion 1120, and a substrate support device 1130. In embodiments, load lock system 1000 corresponds to a load lock 120 controlled by autonomous load lock engine 152 of FIG. 1A.

In some embodiments, a substrate 1140 may be placed on the support device 1130. In some embodiments no substrates may be supported by substrate support device 1130. In some embodiments, more than one substrate may be supported by substrate support device 1130 (not shown in figures). Substrate support device 1130 may include a heated support, a cooled support, a chuck (e.g., an electrostatic chuck or vacuum chuck), and so on.

In some embodiments, substrate support device 1130 may be configured to move vertically up or down within the load lock chamber 1100. In some embodiments, substrate support device 1130 may be configured to rotate within the chamber.

In further embodiments, vertical movement of the substrate support device 1130 within the load lock chamber 1100 may be effected by a mechanical actuator (not shown in FIGS). One of ordinary skill in the art, having the benefit of this disclosure, will be able to design multiple methods and systems employing various types of mechanical actuators to accomplish the above function.

A load lock chamber in a vacuum processing system is used to allow substrates, such as silicon wafers or other substrates, to be loaded and unloaded without disrupting the vacuum environment of a main process chamber or transfer chamber.

The substrate support of a load lock chamber typically refers to the structure or device that holds the substrate in place. It is designed to securely hold the substrate while ensuring that it can be moved into and out of the load lock chamber with ease and without damage. Some substrate supports are flat platforms or trays on which the substrate rests. These may be static or include mechanisms for rotation or other movement, such as vertical movement. Some substrate supports may also include clamping or other securement mechanisms to keep the substrate in place, particularly during any movements. In some embodiments, the substrate support has thermal control capabilities. For instance, the substrate support can be heated or cooled to heat or cool supported substrates and/or maintain the substrates at a particular temperature. Substrate supports may include embedded heating elements that apply resistance heating in one or more zones, may include optical heating, and so on. Substrate supports may additionally or alternatively include cooling mechanism, such as channels through which a coolant is flowed to provide liquid cooling of supported substrates.

A substrate 1140 may be transferred in to the load lock chamber 1100 through first door portion 1110, and then out through second door portion 1120, for processing. Similarly, a substrate may be transferred into the load lock chamber 1100 through second door portion 1120, and out through first door portion 1110. First and second door portions 1110, 1120 may be ports that include slit valves that can open to permit a robot arm to pick or place a substrate from/on the substrate support and that can close to seal off an interior of the load lock chamber. A pressure of the load lock chamber may then be adjusted. A first and/or a second substrate (not shown in figures) may rest on support device 1130. One of ordinary skill in the art, having the benefit of this disclosure, will be able to envision multiple mechanisms, and structures for support device 1130, to support the one or more than one substrate.

The first and second door portions 1110 and 11120 may comprise any sort of sealable portions that may provide a pressure seal against a one or more pressures exterior of the load lock. In some embodiments, the load lock may control an ambient pressure of the chamber, and raise or lower the pressure as necessitated by the electronics or substrate manufacturing system at large.

In some embodiments, more than two door portions may be used. In some embodiments, the first and second door portions 1110 and 1120 may be adjacent, or inset into orthogonal sidewalls of load lock chamber 1100.

In some embodiments, sensing subsystem 1600 of load lock system 1000 may comprise a key part health monitor 1322 which may include a sensor on first and second door portions 1110 and 1120 that are physical deformation sensors 1632 and 1634 placed in locations proximate the door portions. These sensors may provide a measurement to sensing subsystem 1600 and thereon to control algorithm 1316 to sense the integrity of the mechanisms associated with first and second door portions 1110 and 1120. In this way, sensors 1632 and 1634 may monitor the part health of the load lock 1100 door mechanisms, and allow the control algorithm to signal to a user of the manufacturing system when the door mechanisms require maintenance.

In some embodiments, key part health monitor 1322 may alternatively, or in addition, include a vibration sensor and/or accelerometer (not shown in FIGS.) coupled to substrate support device 1130 or a mechanical actuator (not shown in FIGS.) for displacing the substrate support device. In some embodiments, this vibration sensor and/or accelerometer may be used to send the integrity or failure of the actuator that is coupled to the substrate support device. In this way, key part health monitor 1322 may monitor the part health of the substrate support device 1130 and an attached actuator, and allow the control algorithm to signal to a user of the manufacturing system when the substrate support device 1130 or the attached actuator require maintenance.

In some embodiments, sensors 1632 and 1634 may comprise one of capacitive sensors, piezoresistive sensors, strain gauges, or any kind of deformation sensor frequently used in electronic device manufacturing. In some embodiments

In some embodiments, the sensing subsystem 1600 can include a particle sensor 1320 including sensor elements 1602 and 1604. In some embodiments, the particle sensor 1320 may be a sensor elements 1602 and 1604 that may include one or more of, or any combination of one or more of: a light scattering sensor, an impactor sensor, an aerosol electrometer, a mass spectrometer, a residual gas analyzer (RGA) sensor, a weight sensor, a surface acoustic wave (SAW) sensor, a corona discharge sensor, or any other particle sensor commonly made of use within electronics manufacturing systems.

In some embodiments, the light scattering sensor may include one or more imaging sensor. In embodiments, one or more imaging sensors may generate images of different regions of an interior of load lock 1100. In some embodiments, the images of the different regions of the interior of load lock 1100 from the one or more imaging sensors may be stitched together to generate a stitched image of the entire interior surface of the chamber. In some embodiments, the imaging sensors capture the visible spectrum of light. In some embodiments, the imaging sensors capture thermal radiation (e.g., infrared light and/or near-infrared light), ultraviolet light and/or visible light.

Although FIG. 1B only depicts two physical spaces for sensor elements 1602 and 1604 to be placed, one of ordinary skill in the art, having the benefit of this disclosure, would be able to envision many such configurations for placing one, or any number and combination of these particle sensors, within the load lock 1100.

In some embodiments particle sensor 1320 may comprise a corona discharge sensor 1624 comprising cathode 1626 and anode 1628. In some embodiments, the cathode 1626 and anode 1628 may be placed integral with the load lock 1100 sidewalls. In other embodiments, the cathode 1626 and anode 1628 may protrude into the load lock chamber 1100. In some embodiments, the corona discharge sensor 1624 may be used in conjunction with an electrometer within the chamber to perform particle detection. A corona discharge sensor (often referred to as a corona discharge ionization detector) in combination with an electrometer can be used for particle detection, such as for air quality monitoring and in the detection of aerosol particles. A corona discharge is a process by which a current flows from an electrode with a high potential into a neutral fluid (usually air) by ionizing that fluid and creating a region of plasma around the electrode. The electrode is usually a thin wire with a high voltage applied to it. The high electric field near the wire causes ionization and a flow of current through the air. As particles pass through the corona discharge region, they become ionized or charged (e.g., they gain or lose electrons, thereby acquiring a net positive or negative charge). After the particles are charged, they move towards a collection electrode under the influence of an electric field. This collection electrode is connected to an electrometer.

An electrometer is a highly sensitive measuring instrument that can measure electric charge or electrical potential difference. When the charged particles hit the collection electrode, they cause a small current to flow, which is measured by the electrometer. By measuring the charge collected over time, it is possible to infer the number of particles that have passed through the detector. This is because each particle carries a certain amount of charge, so by measuring the total charge collected, and knowing the charge per particle, one can calculate the total number of particles. Additionally, larger particles tend to carry more charge, so it is also possible to make determinations about the size distribution of the particles. This makes it possible to count and sometimes size particles in a gas or air sample. These measurements can then be used to determine when to perform one or more remedial actions, such as an automated clean operation. For example, measurements from any of the above mentioned particle sensors may be used to determine when to invoke a recovery subsystem.

Although FIG. 1B depicts two physical spaces for cathode 1626 and anode 1628 to be placed, one of ordinary skill in the art, having the benefit of this disclosure, would be able to envision many such configurations for this cathode 1626 and anode 1628, or any additional cathodes and anodes, to be placed within the load lock 1100.

In some embodiments the particle sensor 1320 may serve to detect foreign materials, or contaminants within the load lock chamber 1100. In some embodiments, contaminants may be solids, or particles, in other embodiments they may be gasses, or vapors.

In some embodiments, ambient sensor 1640 including sensor elements 1642 and 1644 may be one or more of, or any combination of one or more of: an ambient temperature sensor, a pressure sensor, a relative humidity (RH) sensor, a surface acoustic wave (SAW) sensor, an electrometer to be used with or without a corona discharge sensor, or any other kind of ambient sensor commonly used within an electronics manufacturing system.

In some embodiments, ambient sensor 1640 may be placed in the ceiling, the floor, or the sidewalls of load lock chamber 1100, and sense one or more ambient characteristic associated with the load lock chamber 1100. Although FIG. 1B depicts two physical spaces for sensor elements 1642 and 1644 to be placed, one of ordinary skill in the art, having the benefit of this disclosure, would be able to envision many such configurations and locations for placing one, or any number of these ambient sensors, within the load lock 1100. Measurements from the ambient sensors may be used to determine a state of the load lock chamber, and whether to perform one or more remedial actions in embodiments.

In some embodiments, a substrate sensor 1670 may be disposed within or on the load lock chamber 1100. In some embodiments, the substrate sensor 1670 may be a mass spectrometer placed above the substrate. In some embodiments, the substrate sensor 1670 may also be a particle detector such as sensor element 1602 or 1604. Although FIG. 1B depicts one physical space for substrate sensor 1670 to be placed, one of ordinary skill in the art, having the benefit of this disclosure, would be able to envision many such configurations and locations for placing one, or any number of these substrate sensors, within the load lock 1100.

In an exemplary embodiment shown in FIG. 1B, the load lock system 1000 comprises a recovery subsystem (corresponding to recover subsystem 1700 of FIG. 4) associated with the load lock 1100. In some embodiments, the recovery subsystem 1700 comprises a remedial subsystem 1704 and a preventative subsystem 1706. In some embodiments, the remedial subsystem 1704 can comprise a purge subsystem 1326, a thermal subsystem 1720, an aerosol subsystem 1730, a UV subsystem 1328, and/or a user indication subsystem 1760. In some embodiments the purge subsystem 1326 can further comprise a vent line 1342 and a pump line 1344. In some embodiments, the user indication subsystem 1760 may include a notification to the user transmitted through computing device (e.g., server) 1310 to user interface 1306.

In some embodiments, the preventative subsystem 1706 can comprise a trap subsystem 1332 comprising a cold trap 1752, and/or an electrostatic trap 1754. In some embodiments, the cold trap 1752 can utilize the vent and pump line 1342 and 1344. In some embodiments, the electrostatic trap further comprises a cathode 1756 and an anode 1758.

A cold trap 1752, also known as a cryotrap, is a device used in scientific and industrial applications to condense all vapors except the permanent gases into a liquid or solid. Cold traps may be used in vacuum systems to prevent contaminants from reaching the vacuum pump, or in cryogenic systems to remove residual gases. A cold trap works by cooling a chamber to a very low temperature, often using liquid nitrogen or a mechanical refrigeration system. The temperature should be low enough to condense the specific vapors that the trap is designed to capture. When a vacuum system is operating, vapors travel from the vacuum chamber toward a vacuum pump. As these vapors pass through the cold trap, they hit the cold surface of the cold trap 1752. Because of the low temperature, the vapors condense on the surface, turning from a gas into a solid or liquid. This effectively removes the vapors from the gas stream and traps them.

Once the vapors have been condensed and captured, they remain in the cold trap 1752 and are thus prevented from reaching the vacuum pump. This helps to protect the pump and maintain the quality of the vacuum. Additionally, this prevents the vapors and particles from reaching a substrate in the load lock chamber. The trapped substances can later be safely disposed of once they are warmed and revert to a less volatile state while no substrate is in the load lock chamber (e.g., as part of an automated clean process).

The effectiveness of a cold trap depends on the types of vapors present (since different substances condense at different temperatures) and the temperature of the cold trap (lower temperatures can condense more types of vapors). The design and surface area of the trap also influence its performance.

Electrostatic trap 1754, also known as an ion trap, is a device used to confine charged particles, often ions, using electric fields. An electrostatic trap 1754 works by ionizing particles (unless they are already ionized). Ionization can be accomplished in several ways, such as through electron impact, photoionization, or chemical ionization. Electrostatic trap 1754 generates a static electric field with a geometry that can confine charged particles. This is typically done using a set of electrodes to which voltages are applied. Ions are trapped within this electric field. They experience an electric force that pushes them toward regions of the trap where the electric potential is minimum (for positively charged ions) or maximum (for negatively charged ions).

The stability of the electrostatic trap 1754 (i.e., its ability to keep ions trapped) depends on the specific geometry of the electric field and the specific voltages applied to the electrodes. There are various designs for ion traps, including the Penning trap (which uses both electric and magnetic fields) and the Paul trap (which uses a time-varying electric field). Once the ions are trapped, they can be manipulated for various purposes. For instance, they might be cooled down to very low temperatures, excited to high energy states, or made to undergo chemical reactions with other ions or neutral particles.

In some embodiments the purge subsystem can utilize the vent and pump lines 1342 and 1344 to purge the load lock chamber 1100 with a gas, liquid, vapor, or a similar substance.

In some embodiments, the purge subsystem can use a purge medium comprising nitrogen, carbon dioxide, dry air, or any other purge medium commonly used within electronics manufacturing.

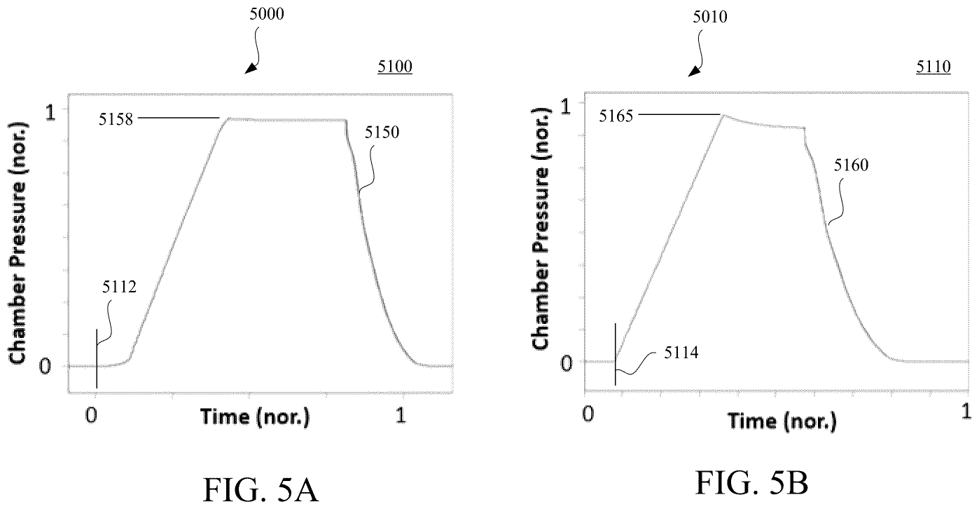

In some embodiments the maximum chamber pressures, pressure ramp, fluid flow and other characteristics of the purge method used by the purge subsystem 1326 can vary according to use of a purge subsystem 1326 utilizing a standard purge method 5000 as shown in FIG. 5A, or a purge clean method 5010 as shown in FIG. 5B. Each of these purge methods will be described in further detail below.

In some embodiments, the purge subsystem 1326 may perform purge clean cycles, which may be repeated any number of times and in an automated fashion that does not involve opening up the load lock chamber to an exterior environment. In embodiments, purge clean cycles may be performed while no substrates are disposed within the load lock chamber or while a test wafer is disposed within the load lock chamber.

In some embodiments the thermal subsystem 1720 can conduct a thermal cycle, to remove moisture or other materials through use of high heat in the load lock chamber 1100. In some embodiments the thermal cycle may include raising the temperature of the load lock 1100 to a temperature that is 150%, 200%, or 300% of the normal operating temperatures of the load lock chamber 1100, and then dropping the temperature back to a normal operating temperature. In some embodiments the thermal cycle may be repeated any number of times. In some embodiments, one or more thermal cycles are performed while one or more substrates are disposed in the load lock chamber. In some embodiments, one or more thermal cycles are performed while no substrates are disposed in the load lock chamber.

In some embodiments, the aerosol subsystem 1730 may be a cryogenic aerosol subsystem, designed to freeze particulates such that they may then be removed by the purge system.

In some embodiments, the cryogenic aerosol subsystem may make use of a cryogenic fluid comprising liquid nitrogen, liquid helium, liquid oxygen, liquid argon, liquid CO₂, or any other kind of cryogenic fluid commonly used within electronics manufacturing.

Cryogenic aerosol systems, also known as cryogenic aerosol cleaning systems, are utilized for particle removal or contamination control in highly sensitive manufacturing environments such as semiconductor wafer production, optics, and high precision manufacturing processes. To perform cryogenic aerosol cleaning, a cryogenic aerosol is produced. This is typically done by taking a cryogenic liquid (like liquid nitrogen or liquid argon), and rapidly expanding it to form a cold gas. As the gas expands, it can cool down enough to freeze a small amount of moisture in the air, forming a cloud of tiny ice particles. This cloud forms a cleaning aerosol. The cryogenic aerosol is then directed onto the surface to be cleaned (e.g., into the interior of the load lock chamber). The tiny ice particles in the aerosol collide with contaminant particles on the surface in the load lock chamber, effectively dislodging them. The kinetic energy of the aerosol particles, along with thermal shock and shrinkage of the contaminant particles due to the extremely low temperature of the aerosol, help in the removal process. After the ice particles dislodge the contaminant particles, both the ice and the contaminants sublimate or evaporate away (since the aerosol is at a much lower temperature than the environment, it rapidly turns back into a gas once it's no longer being cooled by contact with the cryogenic liquid). This process may leave little or no residue on the surface, and the gaseous contaminants can be removed from the environment using appropriate filtration or extraction systems.

The cryogenic cleaning process is dry, non-abrasive, and residue-free, which makes it suitable for applications where traditional cleaning methods may not be appropriate or effective. It is especially useful for removing small particles (micron and sub-micron sizes), and it can clean surfaces without damaging sensitive components or leaving any residue that could interfere with the performance of the cleaned device.

In some embodiments, the UV subsystem 1328 may emit short-wavelength UV light to break down organic material present within the chamber, after which, the purge subsystem 1326 may be used to remove the organic material. Ultraviolet (UV) cleaning systems use UV light, particularly UV-C light, to disinfect surfaces and air. UV-C light is germicidal, meaning it can inactivate microorganisms, such as bacteria, viruses, and fungi. The cleaning system includes a UV-C light source, typically a lamp or LED that produces UV-C light, which is electromagnetic radiation with a wavelength in the range of 200-280 nanometers. The system exposes the target area—whether it's a surface, liquid, or air—to the UV-C light. UV-C light may be absorbed by the DNA and RNA of microorganisms. This absorption leads to a process called photodimerization, where adjacent pyrimidine bases in the DNA or RNA form a covalent bond. This disrupts the structure of the genetic material and prevents the microorganism from reproducing and infecting. Essentially, it inactivates the microorganisms, rendering them harmless.

UV cleaning systems offer several advantages, including the fact that they use no chemicals, leave no residue, and are capable of disinfecting air, water, and surfaces. The effectiveness of UV cleaning can depend on factors such as the intensity and duration of UV-C exposure, the distance from the light source, and the presence of any particles that might shield microorganisms from the light. Consequently, UV cleaning systems are often used as part of a broader set of cleaning and disinfection strategies. For example, the UV subsystem 1328 may be used in combination with aerosol subsystem and/or purge subsystem.

In some embodiments, the remedial subsystems may be triggered by the control algorithm 1316 (described below in reference to FIG. 3), which may be executed by automated prevention/recovery manager 154 of autonomous load lock engine 152, while the preventative subsystems, such as the trap subsystems 1332 comprising the cold trap 1752 and the electrostatic trap 1754 including cathode 1756 and anode 1758, may be selectively triggered by the control algorithm 1316, or may otherwise always be engaged. In some embodiments, the electrostatic trap 1754 may include a cathode 1756 and an anode 1758. In some embodiments, the cathode 1756 and anode 1758 may be placed integral with the load lock 1100 sidewalls. In other embodiments, the cathode 1756 and anode 1758 may protrude into the load lock chamber 1100. Although FIG. 1B depicts two physical spaces for anode 1756 and cathode 1758 to be placed, one of ordinary skill in the art, having the benefit of this disclosure, would be able to envision many such configurations for this cathode 1756 and anode 1758, or any additional cathodes and anodes, within the load lock 1100.

In some embodiments, the electrostatic trap 1754 subsystem is designed to attract electrically charged particles during use of the load lock 1100. During a gas purge of the system, the charge of the electrostatic trap 1754 may be turned off, allowing the particles typically held and attracted by the electrostatic trap 1754 subsystem to be removed via the gas purge subsystem 1326. In other embodiments, the electrostatic trap 1754 may remain engaged during a gas purge.

In some embodiments, the cold trap 1752 can utilize the vent and pump line 1342 and 1344 to introduce a cold fluid designed to cool the surfaces of the load lock 1100, or any other surfaces in the chamber. As the cold trap 1752 begins to function, gasses or substances within the chamber can condense onto the cold surfaces of the chamber, including side wall, ceiling, and bottom surfaces. After, a purge method using gas purge subsystem 1326 may be used to remove the condensed materials from the chamber.

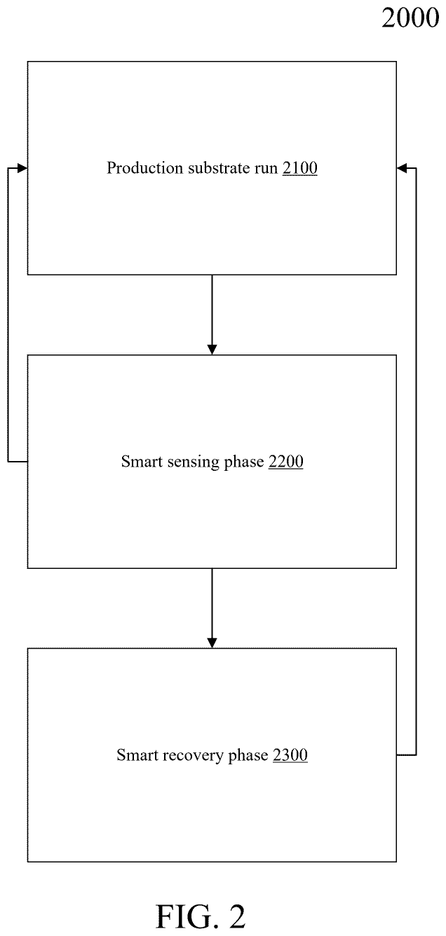

FIG. 2 illustrates an exemplary “smart,” and a non-conventional production flow 2000 that takes advantage of sensing and recovery subsystems 1600 and 1700 of FIG. 4. This “smart” and non-conventional production flow 2000 can be in contrast to a conventionally used, or traditional, process for preventative maintenance of a load lock.

In an example of a conventional process for preventative maintenance of a load lock, a conventional production flow can comprise a production substrate run, a routine particle qualification, a time-based scheduled qualification, part maintenance, and post-maintenance qualification.

In a conventional system, problems within the load lock chamber or substrate may not be discovered until routine particle qualification, or until it comes time to perform a time-based scheduled qualification. These routines and schedules can be spaced apart, and require rigorous time-keeping and care to upkeep the load lock system and chamber. In addition, the inspection and qualification processes can be susceptible to human error and may be performed in a manner that is inconsistent, or less than satisfactory.

In the case an issue with the substrate or load lock system is identified, an intensive part maintenance may be performed. Aside from the negative attributes of such a process, as described above, the manufacturing system itself may be shut down, and production may be put on hold while part maintenance is carried out on the load lock system.

Once part maintenance is completed, post-maintenance qualification must be performed and passed before a production substrate run can be resumed. These showcase just some of the issues with a conventional process for preventative maintenance of a load lock in use for production, including inspecting and upkeeping a load lock system in a manufacturing setting.

In a separate example, and in some embodiments, a non-conventional production flow may be described, comprising a production substrate run 2100, a smart sensing phase 2200, and a smart recovery phase 2300.

In at least one embodiment seen in FIG. 2, a non-invasive smart sensing phase 2200 is ran during and/or after each production substrate run 2100. A production substrate run 2100 may include inserting a production substrate into a load lock through a first port and placing the production substrate onto a substrate support in the load lock by a first robot. The production substrate may be placed into the load lock while the load lock is under vacuum. A gas inlet or vent (e.g., purge line) may be opened minimally to allow for a slow increase in the pressure within the load lock. Additionally, the production substrate may be cooled while in the load lock. Once the production substrate is cooled and/or the load lock reaches a target pressure (e.g., atmospheric pressure), a second port may be opened, and a second robot may retrieve the production substrate from the load lock.

The non-invasive smart sensing phase 2200 may be performed in parallel with the production substrate run 2100 or after completion of a production substrate run 2100. The non-invasive smart sensing phase 2200 may include performing one or more non-invasive measurements using any one or more of the sensors described hereinabove. The measurements may be processed using a rules-based engine and/or one or more trained machine learning models to determine whether to perform any remedial actions.

Use of the smart sensing phase 2200 allows for a higher frequency of surveying and measuring degradation within the load lock system 1000. Unlike conventional flow processes that have long intervals between inspections, process flow 2000 can continuously and autonomously scan the load lock system 1000 for errors.

When errors occur and/or processing logic determines that a remedial action should be performed, the system promptly detects such errors and/or notifies a user of recommended maintenance or addresses the issue using the smart recovery phase 2300 and recovery subsystems 1700.

In some embodiments, the smart recovery phase 2300 may include activating at least one of, or any combination of, subsystems corresponding to recovery subsystem 1700 (as was discussed with reference to FIGS. 1B and 4). This may include engaging any one of, or any combination of the subsystems of the remedial subsystem 1704 or preventative subsystems 1706. This can include activating any one or more of the purge subsystem 1326, the thermal subsystem 1720, the aerosol subsystem 1730, the UV subsystem 1328, the user indication subsystem 1760, the trap subsystem 1332 including a cold trap 1752, or an electrostatic trap 1754.

The non-invasive smart recovery phase 2300 may be performed in parallel with the production substrate run 2100 or after completion of a production substrate run 2100. The non-invasive smart-recovery phase 2300 may be performed while one or more substrates are present within load lock chamber 1100, or when the chamber is empty of any substrates. The non-invasive smart recovery phase may be performed automatically and autonomously, or alternatively, may be engaged by user of the system.

The production substrate run 2100, smart sensing phase 2200, and/or smart recovery phase 2300 may be executed by a controller in embodiments, such as by autonomous load lock engine 152 of FIG. 1.

In an exemplary embodiment, FIG. 3 illustrates a computing subsystem 1300 (e.g., which may correspond to controller 150 of FIG. 1) which may be used to control the sensing and recovery subsystems 1600 and 1700. The computing subsystem 1300 may comprise a computing device 1310 comprising a processor 1312, in electronic communication with a memory 1314 comprising a control algorithm 1316, which may correspond to autonomous load lock engine 152 and/or automated prevention/recovery manager 154 of FIG. 1. The computing device 1310 may be in electronic communication with the load lock system 1000 subsystems via communications channels 1352 comprising a communications channel 1360 for receiving inputs from for the sensing subsystem 1600, a communications channel 1370 for transmitting instructions to the recovery subsystem 1700, and a communications channel 1380 for transmitting and receiving information to user interface 1306.

In some embodiments, computing device 1310 may continually be receiving data from communications channel 1360. In some embodiments, processor (e.g., server processor) 1312 may execute a rule-based control algorithm 1316 to choose whether to activate recovery subsystem 1700 via communication channel 1370. In some embodiments, control algorithm 1316 may communicate with a pre-trained machine learning model, which can intake specific sensor data from communications channel 1360, and output specific instructions for which remedial subsystems 1704 of recovery subsystem 1700 to activate, when to activate remedial subsystems 1704, and so on.

In some embodiments, detection of foreign particles within the load lock chamber 1100 may cause the control algorithm 1316 to trigger a purge subsystem 1326, electrostatic trap (e.g., electrostatic trapping subsystem) 1754, a cryogenic aerosol subsystem 1732, or any other combination of these mechanism to remove foreign particles (e.g., release trapped particles and then purge the trapped particles) from with the load lock chamber 1100. One of ordinary skill in the art, having the benefit of this disclosure, will be able to envision a number of additional subsystems for removal of foreign particles from within the load lock 1100.

In some embodiments, detection of organic contaminants within load lock chamber 1100 may cause the control algorithm 1316 to trigger a UV light emitter 1740, a cold trap 1752, a purge subsystem 1326 (e.g., a gas purge system), or any combination of these mechanisms to remove the organic contaminants. One of ordinary skill in the art, having the benefit of this disclosure, will be able to envision a number of additional subsystems for removal of organic materials from within the load lock 1100.

In some embodiments, detection of moisture within load lock chamber 1100 may cause the control algorithm 1316 to trigger a thermal subsystem 1720, or heater within the load lock 1100 to reduce humidity. In addition, a purge subsystem 1326 may server to remove moisture from within the load lock chamber 1100. One of ordinary skill in the art, having the benefit of this disclosure, will be able to envision a number of additional subsystems for removal of moisture from within the load lock 1100.

In some embodiments, detection of a part failure may cause control algorithm 1316 to trigger an indication to worker, or a user of the system 1000, that a part replacement and/or maintenance is required.

In an exemplary embodiment, FIG. 4 illustrates how control algorithm 1316 may communicate with a variety of associated subsystems 1315 including a sensing subsystem 1600, a recovery subsystem 1700 including both a remedial subsystem 1704 and a preventative subsystem 1706, a chamber subsystem 1780, including both a vacuum subsystem 1336, and a pump line (e.g., mechanical subsystem) 1342 as was discussed above with respect to FIG. 1B. In some embodiments, the sensing subsystem 1600 can include a particle sensor 1320, and a key part health monitor 1322. In some embodiments the remedial subsystem 1704 can include a purge subsystem 1326, or UV organic removal subsystem 1328. In some embodiments the prevention subsystem 1706 can include a particle trapping subsystem 1332. In some embodiments the vacuum subsystem 1336 can include a vent 1338 and pump 1340 hardware. In some embodiments the pump lines (e.g., mechanical subsystem) 1342 can include substrate transfer mechanism 1401.

As seen in the embodiment shown in FIG. 4, control algorithm 1316 may communicate directly with a plurality of associated subsystems 1315, in order to conduct detection and recovery in a smooth and efficient manner.

In embodiments, purge subsystem 1326 may be controlled to perform one or more purge clean cycles to remove particle buildup from an interior of a load lock chamber. The purge clean cycles may include aggressive venting of air and/or gases into the load lock chamber over a short time period and pumping down the load lock chamber to very low pressures that may be below standard operating pressures of the load lock in embodiments. In embodiments, a high initial pressure ramp is used to quickly increase pressure within the load lock and dislodge particles from surfaces. The high initial pressure ramp may be, for example, a rate of pressure increase of at least 10 Torr/sec in embodiments.

In an exemplary embodiment seen in FIG. 5A, the purge subsystem 1326 can perform a purge method that is standard purge method 5000. Purge characterization chart 5100 illustrates a characterization chart of an embodiment of a standard purge method 5000. Purge characterization chart 5100 shows a vent cycle in which a gas and/or air is vented slowly into a load lock chamber and a pump cycle in which the load lock chamber is pumped down to a target pressure. The purge characterization chart 5100 shows pressure, flow rate and pump status and/or pressure ramp for each of the vent cycle and the pump cycle. The purge method 5000 may be performed, for example, while a substrate is in a load lock chamber and while the load lock chamber is deemed “clean” (e.g., autonomous load lock engine 152 has not indicated that an automated cleaning action should be performed).

In some embodiments the characterization chart 5100 can comprise start of a vent “on time” 5112, into which a purge medium is introduced into the load lock chamber 1100. In some embodiments the purge method 5000 can comprise a maximum flow and/or a maximum pressure ramp. In some embodiments the characterization chart 5100 can comprise a chamber pressure characterization line 5150 comprising a maximum pressure denoted by 5158. In some embodiments the purge method 5000 can comprise a wait time between on-time for the venting and pumping. In some embodiments, the purge method 5000 can comprise a pump on-time that indicates an amount of time during which the pump is activated. As shown, there is a slow ramp up of pressure after the vent “on time” 5112, indicating that the pressure is gradually increased initially. The pressure ramp may be, for example, about 5 Torr/sec or less.

In some embodiments, a slope for pressure 5150 (referred to as pressure ramp) can denote the speed at which pressure is changing within the chamber. In some embodiments, a steeper slope can denote a sharper, or more aggressive, introduction of a purge medium into the chamber. A steeper slope can therefore, in some embodiments, denote a purge method that is more effective at removing materials from within the chamber, due to the faster introduction of the purge medium. A less steep slope can denote a more gradual, or more subtle introduction of fluid into the chamber. Although maximum flow and maximum pressure are some characteristics of the gas purge system, the rate of change in flow of the gas purge medium and rate of change in pressure in the chamber (e.g., pressure ramp) are also useful characteristics for measuring the effectiveness of a gas purge method as well.

In some embodiments, the decreasing slope portion for pressure 5150 can denote the speed at which pressure is lowering within the chamber during a pump on time. In some embodiments, a steeper slope can denote a sharper, or more aggressive, extraction of a purge medium from the chamber. A less steep slope can denote a more gradual, or more subtle extraction of fluid from the chamber. The rate of change in pressure of the chamber, as well as the minimum pressure reached, are useful characteristics for measuring the effectiveness of a purge method.

In an exemplary embodiment seen in FIG. 5B, the purge subsystem 1326 can comprise a purge clean method 5010 that is more aggressive than the standard purge method 5000. The purge clean method 5010 may be performed as a remedial action in order to clean an interior of a load lock in embodiments. Purge characterization chart 5110 is a characterization chart of an embodiment of a purge clean method 5010. In some embodiments, the purge characterization chart 5110 can comprise a start of a vent “on time” 5114. In some embodiments the purge clean method characterization chart 5110 can comprise a pressure characterization line 5160 comprising a maximum pressure 5165. In some embodiments, the purge clean method 5010 can comprise a wait time between vent and pump “on-times”. In some embodiments the purge clean method 5010 can comprise a pump “on time”. In some embodiments, the purge clean method characterization chart region 5110 can comprise a pressure characterization line 5160 (or alternatively a flow characterization line) comprising a slope that represents the pressure ramp. As shown, the pressure may immediately start increasing rapidly after the start of the vent “on time” 5114, without an initial gradual pressure increase. In embodiments, the initial pressure ramp is about 10 Torr/sec, 15 Torr/sec, 20 Torr/sec, 30 Torr/sec, 50 Torr/sec, 100 Torr/sec, 150 Torr/sec, 200 Torr/sec or higher. In some embodiments, the initial pressure ramp is between 10 Torr/sec and 200 Torr/sec. In embodiments, the initial pressure ramp is between 10 Torr/sec and 50 Torr/sec. This may agitate particles and cause the particles to become airborne. The airborne particles may then be vented from the chamber, effectively cleaning the chamber.

In some embodiments, the slope for pressure (e.g., pressure ramp) can denote the speed at which pressure is changing within the chamber. In some embodiments, a steeper slope can denote a sharper, or more aggressive, introduction of a purge medium into the chamber. A steeper slope can therefore, in some embodiments, denote a purge method that is more effective at removing materials from within the chamber, due to the faster introduction of the purge medium. A less steep slope can denote a more gradual, or more subtle introduction of fluid into the chamber.

In some embodiment, the method 5010 can comprise a pump “on time”. In some embodiments the purge characterization chart (or chart region) 5110 can comprise a pressure characterization line 5160 comprising a decreasing pressure slope of the pump on time.

In some embodiments, the decreasing slope for pressure can denote the speed at which pressure is changing within the chamber. In some embodiments, a steeper slope can denote a sharper, or more aggressive, extraction of a purge medium from the chamber. A less steep slope can denote a more gradual, or more subtle extraction of fluid from the chamber. The rate of change in pressure of the chamber, as well as the minimum pressure reached, are useful characteristics for measuring the effectiveness of a purge method.

As can be seen from comparing purge methods 5000 and 5010 in FIGS. 5A-B, in an embodiment of the purge methods, during purge clean method 5010, much higher flow is reached both in an initial flow velocity and an initial flow rate when compared to standard purge method 5000. In embodiments, an initial pressure ramp of greater than 10 Torr/sec is used for the purge clean method 5010. In some embodiments, standard purge method 5000 initiates with an initial purge flow velocity between 0 to 1 m/s, while purge clean method 5010 initiates with an initial purge flow velocity greater than 2 m/s (e.g., greater than 3 m/s, greater than 4 m/s, greater than 5 m/s, greater than 6 m/s, greater than 7 m/s, greater than 8 m/s, and so on). In some embodiments, standard purge method 5000 initiates with an initial purge flow rate below 100 sccm/liter, while purge clean method 5010 initiates with an initial purge flow rate greater than 100 sccm/liter (e.g., greater than 200 sccm/liter, greater than 300 sccm/liter, greater than 400 sccm/liter, greater than 500 sccm/liter, greater than 600 sccm/liter, greater than 700 sccm/liter, greater than 800 sccm/liter, and so on). In some embodiments, the initial period of time can be defined from the start of the purge method, until the chamber pressure has reached a target pressure (e.g., 10 Torr, 20 Torr, 30 Torr, 40 Torr, 50 Torr, etc.). In some embodiments, an initial pressure ramp of greater than 10 Torr/sec, greater than 15 Torr/sec, greater than 20 Torr/sec, etc. is used for the purge clean method 5010.

As can be seen from comparing purge methods 5000 and 5010 in FIGS. 5A-B, in an embodiment of the purge methods, during standard purge method 5000 the maximum flow rate is lower than the maximum flow rate during the purge clean method 5010. Additionally, the initial pressure ramp is about 5 Torr/sec or lower.

As can be seen from comparing purge methods 5000 and 5010 in FIGS. 5A-B, in an embodiment of the purge methods, during standard purge method 5000 the maximum chamber pressure is higher than the maximum chamber pressure during the purge clean method 5010. In some embodiments, the maximum chamber pressure may be sustained for a period of time, while maximum chamber pressure may be sustained for a very short period of time, or not sustained at all.

As can be seen from comparing purge methods 5000 and 5010 in FIGS. 5A-B, in an embodiment of the purge methods, during standard purge method 5000 the vent “on time” duration is much longer than the vent “on time” duration during the purge clean method 5010.

As can be seen from comparing purge methods 5000 and 5010 in FIGS. 5A-B, in an embodiment of the purge methods, during standard purge method 5000 the wait time duration between the vent phase and pump phase is much longer than the wait time duration between the vent phase and the pump phase during the purge clean method 5010.

As can be seen from comparing purge methods 5000 and 5010 in FIGS. 5A-B, in an embodiment of the purge methods, during standard purge method 5000 the pump “on time” duration is much shorter than the pump “on time” duration during the purge clean method 5010.

As can be seen from comparing purge methods 5000 and 5010 in FIGS. 5A-B, in an embodiment of the purge methods, lower load lock chamber pressure is reached at the conclusion of the purge clean method 5010 when compared to the standard purge method 5000.

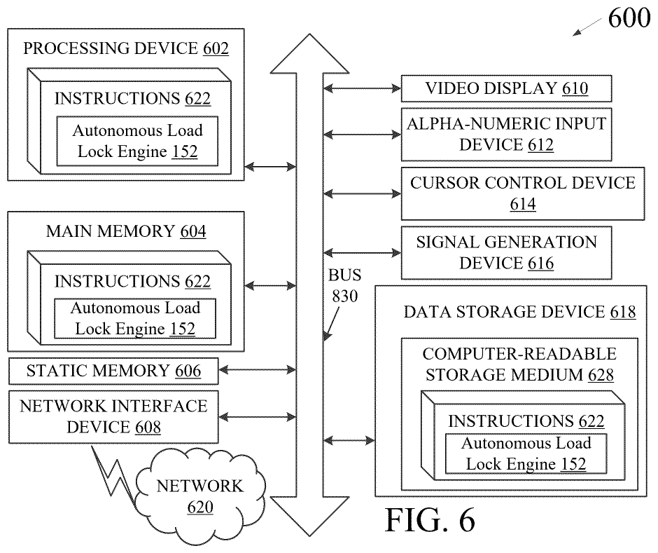

FIG. 6 illustrates a diagrammatic representation of a machine in the example form of a computing device 600 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, the computing device 600 may correspond to a controller for a tool cluster and/or load lock of a substrate processing system. For example, computing device 600 may correspond to controller 150 of FIG. 1A.

The example computing device 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), hard disk (magnetic storage) etc.), and a secondary memory (e.g., a data storage device 618), which communicate with each other via a bus 630.

Processing device 602 represents one or more general-purpose processors such as a microprocessor, central processing unit, or the like. More particularly, the processing device 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 602 may also be one or more special-purpose processing devices such as an application specific integrated circuit (ASIC), a field programmable gate array (FPGA), a digital signal processor (DSP), network processor, or the like. Processing device 602 is configured to execute the processing logic (instructions 622) for performing the operations and steps discussed herein.

The computing device 600 may further include a network interface device 608. The computing device 600 also may include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 616 (e.g., a speaker).

The data storage device 618 may include a machine-readable storage medium (or more specifically a computer-readable storage medium) 628 on which is stored one or more sets of instructions 622 embodying any one or more of the methodologies or functions described herein. The instructions 622 may also reside, completely or at least partially, within the main memory 604 and/or within the processing device 602 during execution thereof by the computing device 600, the main memory 604 and the processing device 602 also constituting computer-readable storage media.

The computer-readable storage medium 628 may also be used to store an autonomous load lock engine 152, and/or a software library containing methods that call an autonomous load lock engine 152. While the computer-readable storage medium 628 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies described herein. The term “computer-readable storage medium” shall accordingly be taken to include, but not be limited to, non-transitory computer readable media such as solid-state memories, and optical and magnetic media.

The modules, components and other features described herein (for example in relation to FIGS. 1A-2) can be implemented as discrete hardware components or integrated in the functionality of hardware components such as ASICS, FPGAs, DSPs or similar devices. In addition, the modules can be implemented as firmware or functional circuitry within hardware devices. Further, the modules can be implemented in any combination of hardware devices and software components, or only in software.

Some portions of the detailed description have been presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a target result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving”, “identifying”, “determining”, “selecting”, “providing”, “storing”, or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the present invention also relate to an apparatus for performing the operations herein. This apparatus may be specially constructed for the discussed purposes, or it may comprise a general purpose computer system selectively programmed by a computer program stored in the computer system. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “of” rather than an exclusive “or.” When the term “about” or “approximately” is used herein, this is intended to mean that the nominal value presented is precise within ±10%.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A load lock, comprising:
a substrate support configured to hold a substrate;
at least one sensor to generate a measurement reflective of a condition within the load lock;
a computing subsystem configured to:
process the measurement to determine the condition within the load lock; and
determine whether to perform a remedial action based on the condition of the load lock; and
a recovery subsystem, configured to perform the remedial action responsive to a determination to perform the remedial action.

2. The load lock of claim 1, wherein the condition comprises at least one of: a contamination state of the load lock, an ambient state of the load lock, a state of a component of the load lock, a presence of a substrate on the substrate support, or a condition of the substrate.

3. The load lock of claim 1, wherein the computing subsystem is further to determine whether the condition within the load lock meets a threshold, wherein the computing subsystem is to determine to perform the remedial action responsive to a determination that the condition meets the threshold.

4. The load lock of claim 1, wherein the computing subsystem is to process the measurement using a trained machine learning model, wherein the trained machine learning model is to a) output a recommendation to perform the remedial action or b) initiate performance of the remedial action.

5. The load lock of claim 1, wherein the condition associated with the measurement comprises at least one of a quantity of foreign particles or a quantity of vapor contaminants.

6. The load lock of claim 1, wherein the at least one sensor comprises a temperature sensor and the measurement comprises a measurement of a temperature within the load lock.

7. The load lock of claim 1, wherein the at least one sensor comprises at least one of a vibration sensor or an accelerometer, and wherein the condition is associated with at least one of a structural failure, a surface damage, or a vibration of at least one of the load lock, the substrate, or a component of the load lock.

8. The load lock of claim 1, wherein the condition is associated with at least one of a surface charge, a warpage, a backside cleanness, an outgassing, or an electrostatic charge of the substrate.

9. The load lock of claim 1, wherein the at least one sensor is selected from the group consisting of: a micro-electromechanical systems (MEMS) sensor, a light scattering sensor, an impactor sensor, an aerosol electrometer, a relative humidity (RH) sensor, a mass spectrometer, a residual gas analyzer (RGA) sensor, a pressure sensor, a physical deformation sensor, or a surface acoustic wave (SAW) sensor.

10. The load lock of claim 1, wherein the recovery subsystem further comprises at least one of a purge clean subsystem, a thermal cycle subsystem, an electrostatic trapping subsystem, a cryogenic aerosol subsystem, an ultraviolet (UV) removal subsystem, or a cold trap.

11. The load lock of claim 1, wherein the remedial action comprises a scheduled maintenance of the load lock.

12. The load lock of claim 1, wherein the remedial action comprises an automated clean cycle of the load lock, wherein the automated clean cycle:
lowers a chamber pressure of the load lock between 10 mT and 1 Torr; and
causes an initial pressure ramp of greater than 10 Torr/sec.

13. The load lock of claim 1, wherein the computing subsystem processes the measurement to determine a condition within the load lock, and determines whether to perform a remedial action based on the condition of the load lock, after a production substrate run, or periodically.

14. The load lock of claim 1, wherein the recovery subsystem further comprises a trap subsystem configured to passively trap particles using either a thermal change, or an electrostatic mechanism.

15. The load lock of claim 14, wherein the trap subsystem comprises an electrostatic trap configured to trap electrically charged particles, wherein the electrostatic trap comprises an anode and a cathode that are embedded into a sidewall of the load lock.

16. A load lock, comprising:
an inlet gas line comprising a first valve;
an outlet gas line;
a vacuum pump coupled to the outlet gas line; and
a controller operatively coupled to the first valve and the vacuum pump, wherein the controller is to perform an automated clean cycle of the load lock, and wherein to perform the automated clean cycle the controller is to:
set a target pressure of between 10 mT and 1 Torr for the vacuum pump; and
actuate the first valve to cause an initial pressure ramp of greater than 10 Torr/sec.

17. The load lock of claim 16, further comprising:
at least one sensor to generate a measurement reflective of a condition within the load lock.

18. The load lock of claim 17, wherein the controller determines to perform the automated clean cycle in response to the measurement of the least one sensor within the load lock, wherein the condition measured comprises a state of contamination in the load lock.

19. The load lock of claim 16, wherein the automated clean cycle comprises introducing gas through the inlet gas line into the load lock with an initial velocity higher than 2 m/s.

20. A method for performing remedial actions in a load lock, comprising:
generating a measurement of a condition within a load lock via at least one sensor;
processing the measurement via a computing subsystem to determine the condition within the load lock;
determining, via the computing subsystem, whether to perform a remedial action based on the condition of the load lock; and
performing the remedial action, via a recovery subsystem, responsive to a determination to perform the remedial action.
